(19) United States
(12) Patent Application Publication
(10) Pub. No.: US 2018/0211576 A1
(43) Pub. Date: Jul. 26, 2018

(54) DOUBLE-SIDED DISPLAYS AND THE TFT ARRAY SUBSTRATES THEREOF, AND MANUFACTURING METHODS OF ARRAY SUBSTRATES

(71) Applicant: Shenzhen China Star Optoelectronics Technology Co., Ltd., Shenzhen, Guangdong (CN)

(72) Inventor: Yong FAN, Shenzhen, Guangdong (CN)

(73) Assignee: Shenzhen China Star Optoelectronics Technology Co., Ltd., Shenzhen, Guangdong (CN)

(21) Appl. No.: 15/038,892

(22) PCT Filed: Apr. 13, 2016
(86) PCT No.: PCT/CN2016/079132

§ 371 Date: Jan. 18, 2018

(30) Foreign Application Priority Data
Mar. 22, 2016 (CN) 201610167663.1

(51) Int. Cl. G09G 3/20; H01L 21/3205

(52) U.S. Cl. CPC G09G 3/20; H01L 21/3205

(57) ABSTRACT

The present disclosure relates to a double-sided display and the TFT array substrate thereof, and a manufacturing method of the array substrate. The TFT array substrate includes a substrate, a first reflective layer arranged on the substrate, a transit media layer covered on the first reflective layer, a gate on the transit media layer and a dielectric layer covering the gate, a light-emitting layer, a source, and a drain on the dielectric layer, an insulation layer above the light-emitting layer, the source, and the drain, a second reflective layer on the insulation layer, and a sealing layer arranged on an outer surface of the second reflective layer. The first reflective layer is of a hollow structure, and reflective areas and transmissive areas are alternately arranged.

### BACKGROUND OF THE INVENTION

### 1. Field of the Invention

The present disclosure relates to double-sided display technology, and more particularly to a double-sided displays and the TFT array substrate thereof, and a manufacturing method of array substrates.

### 2. Discussion of the Related Art

With respect to conventional double-sided displays adopting transmissive panels, two liquid crystal display panels and the corresponding backlight source are configured, which results in a thicker thickness and higher power consumption. In particular, a higher brightness of the display panel is needed when displaying in outdoor. Under the circumstance, a high brightness of the display device requires high power consumption. FIG. 1 is a schematic view of the conventional double-sided liquid crystal display.

### SUMMARY

According to the present disclosure, the double-sided displays and the TFT array substrate thereof, and the manufacturing method of the array substrates are proposed to reduce the power consumption, and to overcome the technical issues, such as complicated structure, heavy dimension and heavy weight.

In one aspect, a TFT array substrate capable of double-sided displaying includes: a substrate; a first reflective layer is arranged on the substrate, the first reflective layer is of a hollow structure, and reflective areas and transmissive areas are alternately arranged; a transit media layer covered on the first reflective layer; a gate on the transit media layer and a dielectric layer covering the gate, wherein the gate is made by graphene oxide (GO); a light-emitting layer, a source, and a drain on the dielectric layer, wherein the source and the drain respectively contacts with the light-emitting layer; an insulation layer above the light-emitting layer, the source, and the drain; a second reflective layer on the insulation layer, the second reflective layer is of the hollow structure, and the reflective areas and the transmissive areas are alternately arranged, wherein a location of the transmissive area of the first reflective layer corresponds to the location of the reflective area of the second reflective layer, and the location of the reflective areas of the first reflective layer corresponds to the location of the transmissive of the second reflective layer; and a sealing layer arranged on an outer surface of the second reflective layer.

Wherein the light-emitting layer, the source and the drain are made by reduced graphene oxide (RGO).

Wherein an oxygen content of the RGO adopted by the source and the drain is smaller than the oxygen content of the RGO adopted by the light-emitting layer.

Wherein the transit media layer is made by SiO2, SiNx, or PI.

Wherein the dielectric layer is made by SiO2 or SiNx.

Wherein the sealing layer is made by SiNx.

In another aspect, a manufacturing method of TFT array substrates capable of double-sided displaying includes: forming a first reflective layer on a substrate, and etching the first reflective layer to be of a hollow structure, and wherein reflective areas and transmissive areas are alternately formed; arranging a transit media layer on the first reflective layer; arranging a gate on the transit media layer and arranging a dielectric layer on the gate; forming a light-emitting layer, a source and a drain on the dielectric layer, wherein the source and the drain respectively contacts with the light-emitting layer; arranging an insulation layer on the light-emitting layer, the source, and the drain; forming a second reflective layer on the insulation layer, etching the second reflective layer to form the hollow structure, and alternately forming the reflective areas and the transmissive areas, wherein a location of the transmissive area of the first reflective layer corresponds to the location of the reflective area of the second reflective layer, and the location of the reflective areas of the first reflective layer corresponds to the location of the transmissive of the second reflective layer, each of the transmissive areas and the reflective areas corresponds to one pixel cell; and forming a sealing layer on an outer surface of the second reflective layer.

Wherein the gate is made by GO materials.

Wherein the light-emitting layer, the source and the drain are made by reduced graphene oxide (RGO).

Wherein an oxygen content of the RGO adopted by the source and the drain is smaller than the oxygen content of the RGO adopted by the light-emitting layer.

Wherein the transit media layer is made by SiO2, SiNx, or PI.

Wherein the dielectric layer is made by SiO2 or SiNx.

Wherein the sealing layer is made by SiNx.

Wherein the gate layer is formed by ink-jet printing, roll to roll, or spinning coating to form the gate.

Compared with the conventional technology, the first reflective layer and the second reflective layer are respectively configured at two sides of the light-emitting layer of the TFT array substrate of the double-sided displays. Not only the structure of the double-sided display is easier, but also the dimension of the double-sided display is greatly reduced. In addition, the GO is adopted to manufacture the light-emitting layer and the electrode layer to enhance the displaying speed of pixels and to enhance the resolution and the sawtooth issues of the displayed images. Also, it is possible to manufacture the flexible double-sided displays by adopting different substrate.

### BRIEF DESCRIPTION OF THE DRAWINGS

FIG. 1 is a schematic view of the conventional double-sided liquid crystal display.

FIG. 2 is a schematic view of the TFT array substrate of double-sided display in accordance with one embodiment.

FIG. 3 is a schematic view showing the single-sided display performance of conventional pixel design.

FIG. 4 is a schematic view showing the double-sided display performance of conventional pixel design.

FIG. 5 is a schematic view showing the single-sided display performance of a oxide-graphene display in accordance with one embodiment.

FIG. 6 is a schematic view showing the double-sided display performance of a oxide-graphene display in accordance with one embodiment.

FIG. 7 is a flowchart of a manufacturing method of the TFT array substrate of double-sided display in accordance with one embodiment.

FIG. 8 is a schematic view of a first reflective layer formed by the manufacturing method of the TFT array substrate of FIG. 7.

FIG. 9 is a schematic view of a gate and a dielectric layer formed by the manufacturing method of the TFT array substrate of FIG. 7.

FIG. 10 is a schematic view of a light-emitting layer, a source and a drain formed by the manufacturing method of the TFT array substrate of FIG. 7.

FIG. 11 is a schematic view of a second reflective layer formed by the manufacturing method of the TFT array substrate of FIG. 7.

FIG. 12 is a schematic view of the double-sided display in accordance with one embodiment.

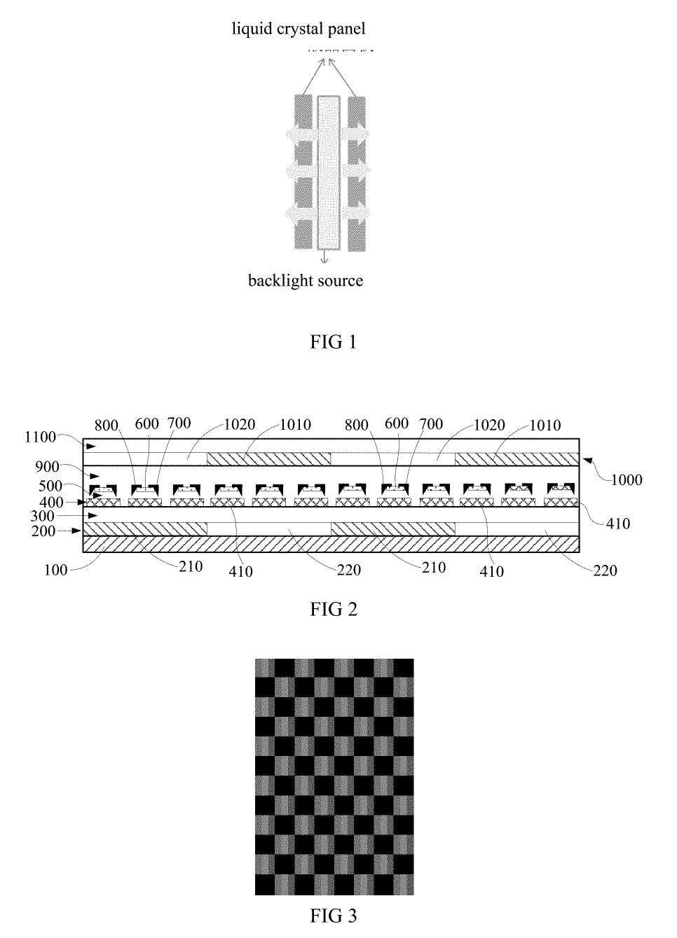

### DETAILED DESCRIPTION OF THE EMBODIMENTS

Embodiments of the invention will now be described more fully hereinafter with reference to the accompanying drawings, in which embodiments of the invention are shown.

FIG. 2 is a schematic view of the TFT array substrate of double-sided display in accordance with one embodiment. The TFT array substrate includes, but not limited to, a substrate 100, a first reflective layer 200, a transit media layer 300, a gate 400, a dielectric layer 500, a light-emitting layer 600, a source 700, a drain 800, an insulation layer 900, a second reflective layer 1000, and a sealing layer 1100.

In particular, the first reflective layer 200 is arranged on the substrate 100. The substrate 100 may be made by materials with great hardiness and high stability, such as glass, metal, PET (polyethylene terephthalate). In other examples, the substrate 100 may be made by soft materials to manufacture flexible panels. Preferably, the first reflective layer 200 is a metallic film, and the first reflective layer 200 is of a hollow structure to form reflective areas 210 and transmissive areas 220 in an alternated manner. With such configuration, a portion of pixel lights are reflected, and a portion of pixel lights may pass through the first reflective layer 200. When one side of the panel displays, the reflective areas 210 reflects the lights to the other side, such that double-sided display may be accomplished.

The transit media layer 300 is arranged on the first reflective layer 200. The transit media layer 300 may be made by SiO2, SiNx, PI, and so on to form a flat layer for insulating oxygen. The gate 400 is arranged on the transit media layer 300. The gate 400 may be made by Graphene oxide (GO). Another purpose of the transit media layer 300 is that the GO may be greatly absorbed. The GO of the gate 400 may be obtained by an enhanced hummers method, which relates to an oxidation reduction method for generating graphene. That is, a portion of graphene being oxidated may generate fully GO. A coating layer may be formed by ink-jet printing, Roll to Roll, or spinning coating, and then an ion etching process or laser etching process is applied to the coating layer to form a gate structure 410.

The dielectric layer 500 arranged on the gate 400 is made by SiO2 or SiNx. The light-emitting layer 600, the source 700, and the drain 800 are arranged on the dielectric layer 500. The source 700 and the drain 800 respectively contacts with the light-emitting layer 600. Preferably, the light-emitting layer 600, the source 700, and the drain 800 are made by reduced graphene oxide (RGO). That is, an oxygen content of the light-emitting layer 600, the source 700, and the drain 800 is smaller than the oxygen content of the GO adopted by the gate 400.

Further, the oxygen contents of the light-emitting layer 600, the source 700, and the drain 800 are different. Preferably, the oxygen contents of the RGO adopted by the source 700 and the drain 800 is smaller than that of the light-emitting layer 600. The light-emitting wavelength of the light-emitting layer 600 may be continuously adjusted via the voltage of the gate 400. The manufacturing method of the light-emitting layer 600 is the same with the GO layer of the gate 400. Similarly, the source 700 and the drain 800 may be made by the same manufacturing method of the gate 400.

In addition, the insulation layer 900 is arranged on the light-emitting layer 600, the source 700, and the drain 800. The insulation layer 900 is characterized by attributes such as oxygen insulation, good thermal conductivity, and capable of providing heat-dissipation channel.

The second reflective layer 1000 is arranged on the insulation layer 900. The second reflective layer 1000 is also a metallic film, and is of the hollow structure, wherein the reflective areas 1010 and the transmissive areas 1020 are formed in an alternated manner. With such configuration, a portion of pixel lights are reflected, and a portion of pixel lights may pass through the second reflective layer 1000. When one side of the panel displays, the reflective areas 1010 reflects the lights to the other side, such that double-sided display may be accomplished.

Preferably, a location of the transmissive areas 220 of the first reflective layer 200 corresponds to the location of the reflective areas 1010 of the second reflective layer 1000, and the location of the reflective areas 210 of the first reflective layer 200 corresponds to the location of the transmissive areas 1020 of the second reflective layer 1000.

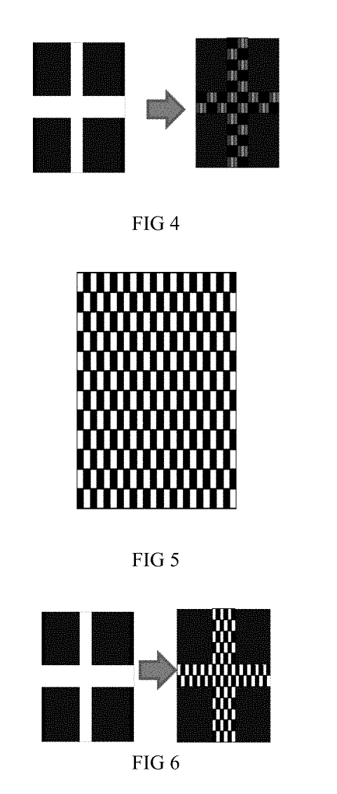

Each of the transmissive areas (220, 1020) and the reflective areas (210, 1010) respectively correspond to a pixel cell. That is, Each of the transmissive areas (220, 1020) and the reflective areas (210, 1010) correspond to three sets of electrode structures, including the gate 400, the light-emitting layer 600, the source 700 and the drain 800. The pixel electrode may be driven by a field sequential color method. Combined with the quick response time attribute of the GO, the resolution rate of the display images and the sawtooth phenomenon occurred at the edges of the display images may be enhanced. Compared with the conventional pixel design, the display performance may be greatly enhanced. FIG. 3 is a schematic view showing the single-sided display performance of conventional pixel design, wherein the black portions relate to the opposite pixels. FIG. 4 is a schematic view showing the double-sided display performance of conventional pixel design. FIG. 5 is a schematic view showing the single-sided display performance of a oxide-graphene display in accordance with one embodiment. FIG. 6 is a schematic view showing the double-sided display performance of a oxide-graphene display in accordance with one embodiment. It is obvious that the display performance (resolution rate and the sawtooth phenomenon) is greatly enhanced.

Further, the sealing layer 1100 is arranged on an outer surface of the second reflective layer 1000. The sealing layer 1100 may be made by SiNx to protect the components from water and oxygen.

Compared with the conventional technology, the first reflective layer and the second reflective layer are respectively configured at two sides of the light-emitting layer of the TFT array substrate of the double-sided displays. Not only the structure of the double-sided display is easier, but also the dimension of the double-sided display is greatly reduced. In addition, the GO is adopted to manufacture the light-emitting layer and the electrode layer to enhance the displaying speed of pixels and to enhance the resolution and the sawtooth issues of the displayed images. Also, it is possible to manufacture the flexible double-sided displays by adopting different substrate.

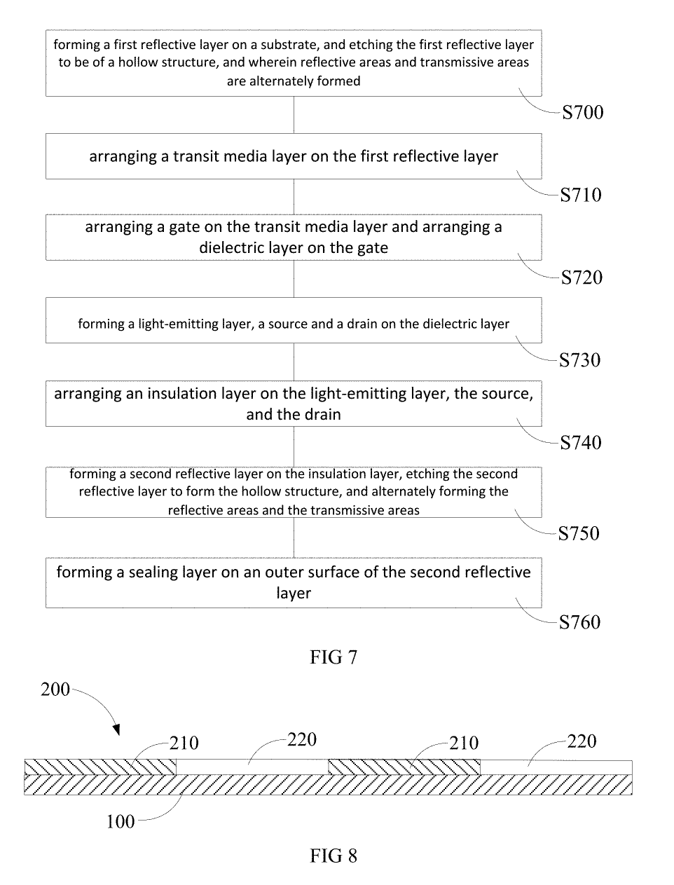

FIG. 7 is a flowchart of a manufacturing method of the TFT array substrate of double-sided display in accordance with one embodiment. The method includes the following steps.

In step S700, forming a first reflective layer on a substrate, and etching the first reflective layer to be of a hollow structure, and wherein reflective areas and transmissive areas are formed in an alternated manner.

In step S700, the substrate 100 may be made by materials with great hardiness and high stability, such as glass, metal, PET (polyethylene terephthalate). In other examples, the substrate 100 may be made by soft materials to manufacture flexible panels.

Preferably, the first reflective layer 200 is a metallic film being coated or being sputtered on the substrate 100. Afterward, the etching or a miniature engraving process is applied to the metallic film to form the hollow structure, an wherein the reflective areas 210 and the transmissive areas 220 are configured in the alternated manner. With such configuration, a portion of pixel lights are reflected, and a portion of pixel lights may pass through the first reflective layer 200. When one side of the panel displays, the reflective areas 210 reflects the lights to the other side, such that double-sided display may be accomplished. FIG. 8 is a schematic view of a first reflective layer formed by the manufacturing method of the TFT array substrate of FIG. 7.

In step S710, arranging a transit media layer on the first reflective layer. The transit media layer may be made by SiO2, SiNx, PI, and so on to form a flat layer for insulating the oxygen.

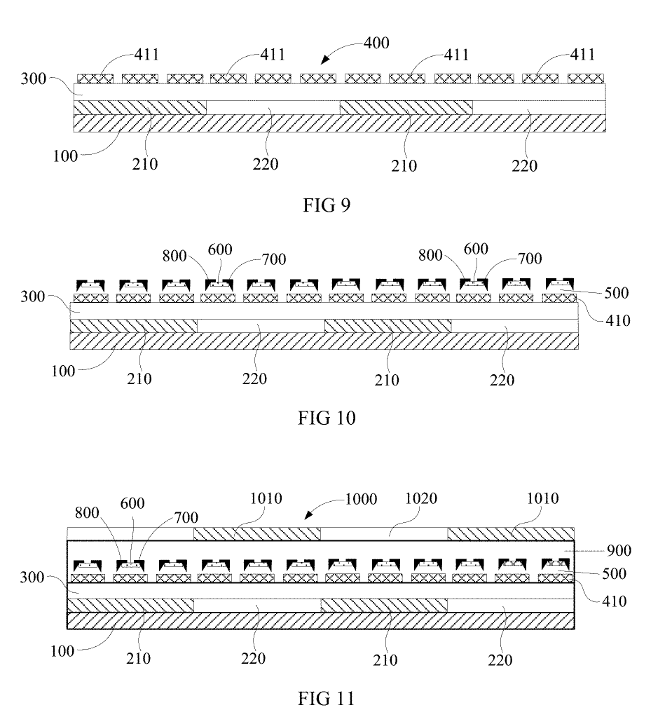

In step S720, arranging a gate on the transit media layer and arranging a dielectric layer on the gate. The gate 400 may be made by GO. Another purpose of the transit media layer 300 is that the GO may be greatly absorbed. The GO of the gate 400 may be obtained by an enhanced hummers method, which relates to an oxidation reduction method for generating graphene. That is, a portion of graphene being oxidated may generate fully GO. A coating layer may be formed by ink-jet printing, Roll to Roll, or spinning coating, and then an ion etching process or laser etching process is applied to the coating layer to form a gate structure 410. The dielectric layer 500 arranged on the gate 400 is made by SiO2 or SiNx. FIG. 9 is a schematic view of a gate and a dielectric layer formed by the manufacturing method of the TFT array substrate of FIG. 7.

In step S730, forming a light-emitting layer, a source and a drain on the dielectric layer, wherein the source and the drain respectively contacts with the light-emitting layer.

In step S730, the light-emitting layer, the source and the drain are formed on the dielectric layer, wherein the source 700 and the drain 800 respectively contacts with the light-emitting layer 600. Preferably, the light-emitting layer 600, the source 700, and the drain 800 are made by RGO. The oxygen contents of the light-emitting layer 600, the source 700, and the drain 800 are different.

Preferably, the oxygen contents of the RGO adopted by the source 700 and the drain 800 is smaller than that of the light-emitting layer 600. The light-emitting wavelength of the light-emitting layer 600 may be continuously adjusted via the voltage of the gate 400. The manufacturing method of the light-emitting layer 600 is the same with the GO layer of the gate 400. Similarly, the source 700 and the drain 800 may be made by the same manufacturing method of the gate 400. FIG. 10 is a schematic view of a light-emitting layer, a source and a drain formed by the manufacturing method of the TFT array substrate of FIG. 7.

In step S740, arranging an insulation layer on the light-emitting layer, the source, and the drain.

In the step, the insulation layer 900 (see FIG. 11) is characterized by attributes such as oxygen insulation, good thermal conductivity, and capable of providing heat-dissipation channel.

In step S750, forming a second reflective layer on the insulation layer, and an etching process is applied to the second reflective layer to form the hollow structure, and wherein the reflective areas and the transmissive areas are arranged in the alternated manner.

The second reflective layer 1000 is arranged on the insulation layer 900. The second reflective layer 1000 is also a metallic film, and is of the hollow structure, wherein the reflective areas 1010 and the transmissive areas 1020 are formed in an alternated manner. With such configuration, a portion of pixel lights are reflected, and a portion of pixel lights may pass through the second reflective layer 1000. When one side of the panel displays, the reflective areas 1010 reflects the lights to the other side, such that double-sided display may be accomplished. The manufacturing method of the second reflective layer 1000 is the same with the manufacturing method of the first reflective layer 200.

Preferably, a location of the transmissive areas 220 of the first reflective layer 200 corresponds to the location of the reflective areas 1010 of the second reflective layer 1000, and the location of the reflective areas 210 of the first reflective layer 200 corresponds to the location of the transmissive areas 1020 of the second reflective layer 1000. FIG. 11 is a schematic view of a second reflective layer formed by the manufacturing method of the TFT array substrate of FIG. 7.

Each of the transmissive areas (220, 1020) and the reflective areas (210, 1010) respectively correspond to a pixel cell. That is, Each of the transmissive areas (220, 1020) and the reflective areas (210, 1010) correspond to three sets of electrode structures, including the gate 400, the light-emitting layer 600, the source 700 and the drain 800. The pixel electrode may be driven by a field sequential color method. Combined with the quick response time attribute of the GO, the resolution rate of the display images and the sawtooth phenomenon occurred at the edges of the display images may be enhanced. Compared with the conventional pixel design, the display performance may be greatly enhanced. FIG. 3 is a schematic view showing the single-sided display performance of conventional pixel design, wherein the black portions relate to the opposite pixels. FIG. 4 is a schematic view showing the double-sided display performance of conventional pixel design. FIG. 5 is a schematic view showing the single-sided display performance of a oxide-graphene display in accordance with one embodiment. FIG. 6 is a schematic view showing the double-sided display performance of a oxide-graphene display in accordance with one embodiment. It is obvious that the display performance (resolution rate and the sawtooth phenomenon) is greatly enhanced.

In step S760, forming a sealing layer on an outer surface of the second reflective layer.

In step S760, also referring to FIG. 2, the sealing layer 1100 may be made by SiNx to protect the components from water and oxygen.

Compared with the conventional technology, the first reflective layer and the second reflective layer are respectively configured at two sides of the light-emitting layer of the TFT array substrate of the double-sided displays. Not only the structure of the double-sided display is easier, but also the dimension of the double-sided display is greatly reduced. In addition, the GO is adopted to manufacture the light-emitting layer and the electrode layer to enhance the displaying speed of pixels and to enhance the resolution and the sawtooth issues of the displayed images. Also, it is possible to manufacture the flexible double-sided displays by adopting different substrate.

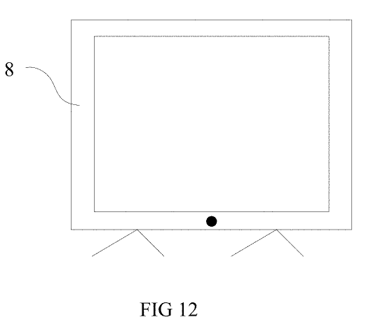

FIG. 12 is a schematic view of the double-sided display in accordance with one embodiment. The double-sided display includes a housing 8 and the TFT array substrate arranged within the housing 8. The TFT array substrate may be referenced in view of the above disclosure, and other components may be conceived by persons skilled in the art, and thus the descriptions are omitted hereinafter.

It is believed that the present embodiments and their advantages will be understood from the foregoing description, and it will be apparent that various changes may be made thereto without departing from the spirit and scope of the invention or sacrificing all of its material advantages, the examples hereinbefore described merely being preferred or exemplary embodiments of the invention.

What is claimed is:

1. A TFT array substrate capable of double-sided displaying, comprising:
a substrate;
a first reflective layer is arranged on the substrate, the first reflective layer is of a hollow structure, and reflective areas and transmissive areas are alternately arranged;
a transit media layer covered on the first reflective layer;
a gate on the transit media layer and a dielectric layer covering the gate, wherein the gate is made by graphene oxide (GO);
a light-emitting layer, a source, and a drain on the dielectric layer, wherein the source and the drain respectively contacts with the light-emitting layer;
an insulation layer above the light-emitting layer, the source, and the drain;
a second reflective layer on the insulation layer, the second reflective layer is of the hollow structure, and the reflective areas and the transmissive areas are alternately arranged, wherein a location of the transmissive area of the first reflective layer corresponds to the location of the reflective area of the second reflective layer, and the location of the reflective areas of the first reflective layer corresponds to the location of the transmissive of the second reflective layer; and
a sealing layer arranged on an outer surface of the second reflective layer.

2. The TFT array substrate claimed in claim 1, wherein the light-emitting layer, the source and the drain are made by reduced graphene oxide (RGO).

3. The TFT array substrate claimed in claim 2, wherein an oxygen content of the RGO adopted by the source and the drain is smaller than the oxygen content of the RGO adopted by the light-emitting layer.

4. The TFT array substrate claimed in claim 1, wherein the transit media layer is made by SiO2, SiNx, or PI.

5. The TFT array substrate claimed in claim 1, wherein the dielectric layer is made by SiO2 or SiNx.

6. The TFT array substrate claimed in claim 1, wherein the sealing layer is made by SiNx.

7. A manufacturing method of TFT array substrates capable of double-sided displaying, comprising:
forming a first reflective layer on a substrate, and etching the first reflective layer to be of a hollow structure, and wherein reflective areas and transmissive areas are alternately formed;
arranging a transit media layer on the first reflective layer;
arranging a gate on the transit media layer and arranging a dielectric layer on the gate;
forming a light-emitting layer, a source and a drain on the dielectric layer, wherein the source and the drain respectively contacts with the light-emitting layer;
arranging an insulation layer on the light-emitting layer, the source, and the drain;
forming a second reflective layer on the insulation layer, etching the second reflective layer to form the hollow structure, and alternately forming the reflective areas and the transmissive areas, wherein a location of the transmissive area of the first reflective layer corresponds to the location of the reflective area of the second reflective layer, and the location of the reflective areas of the first reflective layer corresponds to the location of the transmissive of the second reflective layer, each of the transmissive areas and the reflective areas corresponds to one pixel cell; and
forming a sealing layer on an outer surface of the second reflective layer.

8. The manufacturing method claimed in claim 7, wherein the gate is made by GO materials.

9. The manufacturing method claimed in claim 7, wherein the light-emitting layer, the source and the drain are made by reduced graphene oxide (RGO).

10. The manufacturing method claimed in claim 9, wherein an oxygen content of the RGO adopted by the source and the drain is smaller than the oxygen content of the RGO adopted by the light-emitting layer.

11. The manufacturing method claimed in claim 7, wherein the transit media layer is made by SiO2, SiNx, or PI.

12. The manufacturing method claimed in claim 7, wherein the dielectric layer is made by SiO2 or SiNx.

13. The manufacturing method claimed in claim 7, wherein the sealing layer is made by SiNx.

14. The manufacturing method claimed in claim 7, wherein the gate layer is formed by ink-jet printing, roll to roll, or spinning coating to form the gate.

15. A double-sided display, comprising:
a TFT array substrate capable of double-sided displaying, the TFT array substrate comprises:
a substrate;
a first reflective layer is arranged on the substrate, the first reflective layer is of a hollow structure, and reflective areas and transmissive areas are alternately arranged;
a transit media layer covered on the first reflective layer;
a gate on the transit media layer and a dielectric layer covering the gate, wherein the gate is made by graphene oxide (GO);
a light-emitting layer, a source, and a drain on the dielectric layer, wherein the source and the drain respectively contacts with the light-emitting layer;
an insulation layer above the light-emitting layer, the source, and the drain;
a second reflective layer on the insulation layer, the second reflective layer is of the hollow structure, and the reflective areas and the transmissive areas are alternately arranged, wherein a location of the transmissive area of the first reflective layer corresponds to the location of the reflective area of the second reflective layer, and the location of the reflective areas of the first reflective layer corresponds to the location of the transmissive of the second reflective layer; and
a sealing layer arranged on an outer surface of the second reflective layer.

16. The double-sided display claimed in claim 15, wherein the gate is made by GO materials.

17. The double-sided display claimed in claim 15, wherein the light-emitting layer, the source and the drain are made by reduced graphene oxide (RGO).

18. The double-sided display claimed in claim 17, wherein an oxygen content of the RGO adopted by the source and the drain is smaller than the oxygen content of the RGO adopted by the light-emitting layer.

19. The double-sided display claimed in claim 15, wherein the transit media layer is made by SiO2, SiNx, or PI.
